(19) United States
(12) Patent Application Publication
(10) Pub. No.: US 2026/0334022 A1
(43) Pub. Date: Oct. 22, 2026

(54) ELECTRONIC DEVICE

(71) Applicant: InnoLux Corporation, Miao-Li County (TW)

(72) Inventors: Yuan-Lin WU, Miao-Li County (TW); Tsung-Han TSAI, Miao-Li County (TW); Kuan-Feng LEE, Miao-Li County (TW)

(73) Assignee: InnoLux Corporation, Miao-Li County (TW)

(21) Appl. No.: 19/555,913

(22) Filed: Mar. 4, 2026

(30) Foreign Application Priority Data
Apr. 18, 2025 (CN) 202510487968.X

(51) Int. Cl. H10K 59/124; H10K 102/00

(52) U.S. Cl. CPC H10K 59/124; H10K 2102/311

(57) ABSTRACT

An electronic device, which is able to be operated in a first state and a second state, is provided. The electronic device includes a stretchable pattern substrate, a first protruding unit, and a second protruding unit. The stretchable pattern substrate has a first portion, a second portion, and a connecting portion connected between the first portion and the second portion. The first protruding unit is disposed on the first portion, and the second protruding unit is disposed on the second portion. A first distance D1 between the first protruding unit and the second protruding unit in the first state and a second distance D2 between the first protruding unit and the second protruding unit along the stretched direction in the second state satisfy the following relationship: 1<D2/D1<2.

### BACKGROUND OF THE DISCLOSURE

### 1. Field of the Disclosure

The present disclosure relates to an electronic device and particularly to an electronic device with a protruding unit on a stretchable pattern substrate.

### 2. Description of the Prior Art

In conventional electronic devices, protruding units are typically disposed on a substrate to support a mask or to position light-emitting units or sensing units during manufacturing processes. Although stretchable electronic devices have been developed in recent years, its substrate is a pattern substrate, which limits available space thereon. Accordingly, how to dispose the protruding unit on the pattern substrate remains a significant issue in this field.

### SUMMARY OF THE DISCLOSURE

An objective of the present disclosure is to provide an electronic device to solve the issue as mentioned above.

The present disclosure provides an electronic device, which is able to be operated in a first state and a second state. The electronic device includes a stretchable pattern substrate, a first electronic unit, a first protruding unit, a second electronic unit, and a second protruding unit. The stretchable pattern substrate has a first portion, a second portion, and a connecting portion connected between the first portion and the second portion. The first electronic unit and the first protruding unit are disposed on the first portion, and the second electronic unit and the second protruding unit are disposed on the second portion. The first protruding unit and the second protruding unit are higher than the first electronic unit and the second electronic unit in a normal direction of the electronic device. When the electronic device is stretched along a stretched direction from the first state to the second state, a first distance D1 between the first protruding unit and the second protruding unit along the stretched direction in the first state and a second distance D2 between the first protruding unit and the second protruding unit along the stretched direction in the second state satisfy the following relationship: 1<D2/D1<2.

In the electronic device of the present disclosure, since the distance between the protruding units disposed on different island portions may be increased after stretching, the electronic device may exhibit noticeable change in size after being stretched. Therefore, the change is easily recognized by the human eye, such that the electronic device has the stretchable characteristic.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a top view of an electronic device operated in a first state and a second state according to a first embodiment of the present disclosure.

FIG. 2 schematically illustrates a top view of an electronic device operated in the first state and the second state according to a variant embodiment of the first embodiment of the present disclosure.

FIG. 3 schematically illustrates a top view of the electronic device operated in the first state according to a second embodiment of the present disclosure.

FIG. 4 schematically illustrates a cross-sectional view of FIG. 3 taken along a cross-sectional line A-A′.

FIG. 5 schematically illustrates a cross-sectional view of FIG. 3 taken along a cross-sectional line B-B′.

FIG. 6 schematically illustrates a top view of an electronic device operated in the first state according to a third embodiment of the present disclosure.

FIG. 7 schematically illustrates a cross-sectional view taken along a cross-sectional line C-C′ of FIG. 6.

FIG. 8 schematically illustrates a top view of an electronic device operated in the first state according to a fourth embodiment of the present disclosure.

FIG. 9 schematically illustrates a cross-sectional view of an electronic device according to a fifth embodiment of the present disclosure.

FIG. 10 schematically illustrates a top view of an electronic device operated in the first state according to a sixth embodiment of the present disclosure.

### DETAILED DESCRIPTION

The contents of the present disclosure will be described in detail with reference to specific embodiments and drawings. It is noted that, for purposes of illustrative clarity and ease of understanding by the readers, the following drawings in the present disclosure are simplified schematic diagrams, and elements therein may not be drawn to scale. The numbers and sizes of the elements in the drawings are merely illustrative and are not intended to limit the scope of the present disclosure.

Certain terms are used throughout the specification and the appended claims of the present disclosure to refer to specific elements. Those skilled in the art should understand that electronic equipment manufacturers may refer to an element by different names, and this document does not intend to distinguish between elements that differ in name but not in function. In the following specification and claims, the terms “comprise”, “include” and “have” are open-ended fashion, so they should be interpreted as “including but not limited to . . . ”.

The ordinal numbers used in the specification and the appended claims, such as “first”, “second”, etc., are used to describe the elements of the claims. This does not mean that the element has any previous ordinal numbers, nor does this represent the order of a certain element and another element, or the sequence in a manufacturing method. These ordinal numbers are merely used to make a claimed element with a certain name be clearly distinguishable from another claimed element with the same name.

Spatially relative terms, such as “above”, “on”, “beneath”, “below”, “under”, “left”, “right”, “before”, “front”, “after”, “behind” and the like, used in the following embodiments merely refer to the directions in the drawings and are not intended to limit the present disclosure.

In addition, when one element or layer is “on” or “above” another element or layer or is “connected to” the another element or layer, it may be understood that the element or layer is directly on the another element or layer or directly connected to the another element or layer, and alternatively, other element or layer may be between the element or layer and the another element or layer (indirectly). On the contrary, when the element or layer is “directly on” the another element or layer or is “directly connected to” the another element or layer, it may be understood that there is no intervening element or layer between the element or layer and the another element or layer. The term “electrically connected” or “coupled” includes means of direct or indirect electrical connection.

As disclosed herein, the terms “approximately”, “essentially”, “about”, or “substantially” generally mean within 20%, 10%, 5%, 3%, 2%, 1%, or 0.5% of the reported numerical value or range. The quantity disclosed herein is an approximate quantity, that is, without a specific description of “approximately”, “essentially”, “about”, or “substantially”, the quantity may still include the meaning of “approximately”, “essentially”, “about”, or “substantially”.

It should be understood that, according to the following embodiments, features of different embodiments may be replaced, recombined or mixed to constitute other embodiments without departing from the spirit of the present disclosure. The features of various embodiments may be mixed arbitrarily and used in different embodiments without departing from or conflicting with the spirit of the present disclosure.

In the present disclosure, the thickness, area, width, height, and distance may be measured using an optical microscope (OM), a scanning electron microscope (SEM) or other approaches, and may be determined by the same picture or two or more pictures, but not limited thereto.

Unless otherwise defined, all terms (including technical and scientific terms) used herein have the same meaning as commonly understood by those skilled in the art. It should be understood that these terms, such as those defined in commonly used dictionaries, should be interpreted as having meaning consistent with the relevant technology and the background or context of the present disclosure, and should not be interpreted in an idealized or excessively formal way, unless there is a specific definition in the embodiments of the present disclosure.

An electronic device of the present disclosure may be a bendable, stretchable, and/or flexible electronic device, but not limited thereto. The electronic device may, for example, include a sensing device, a light-emitting device, a display device, an antenna device, a touch device, a tiled device, or other suitable electronic devices, but not limited thereto. The sensing device of the present disclosure mainly is an optical type sensing device, but not limited thereto. The sensing device may, for example, be a sensing device used for detecting variation in capacitances, light, heat, or ultrasound, but not limited thereto. The sensing device may, for example, include a bio-sensor, a touch sensor, a fingerprint sensor, other suitable sensors, or any combination of the aforementioned sensors. The display device may, for example, be applied to a laptop, a public display, a tiled display, a car display, a touch display, a TV, a monitor, a smartphone, a tablet, a light source module, a lighting equipment, or an electronic device applied to the aforementioned products, but not limited thereto. The display device may include a light-emitting element, a fluorescent material, a phosphor material, other suitable display media, or a combination thereof, but not limited thereto. The light-emitting element may, for example, include an organic light-emitting diode (OLED), a mini light-emitting diode (mini LED), a micro light-emitting diode (micro LED), or a quantum dot light-emitting diode (e.g., QLED or QDLED), but not limited thereto. The antenna device may include liquid crystal antenna or antennas of other types, but not limited thereto. The tiled device may, for example, include a tiled display device or a tiled antenna device, but not limited thereto. Furthermore, the appearance of the electronic device may be, for example, rectangular, circular, polygonal, a shape with curved edges, curved or other suitable shapes. The electronic device may have peripheral systems such as a driving system, a control system, a light source system, a shelf system, etc. The electronic device may include electronic elements, in which the electronic elements may include a passive element and an active element, and for example include a capacitor, a resistor, an inductor, a diode, a transistor, a sensor, etc. It is noted that the electronic device of the present disclosure may be any combination of the above-mentioned devices, but not limited thereto.

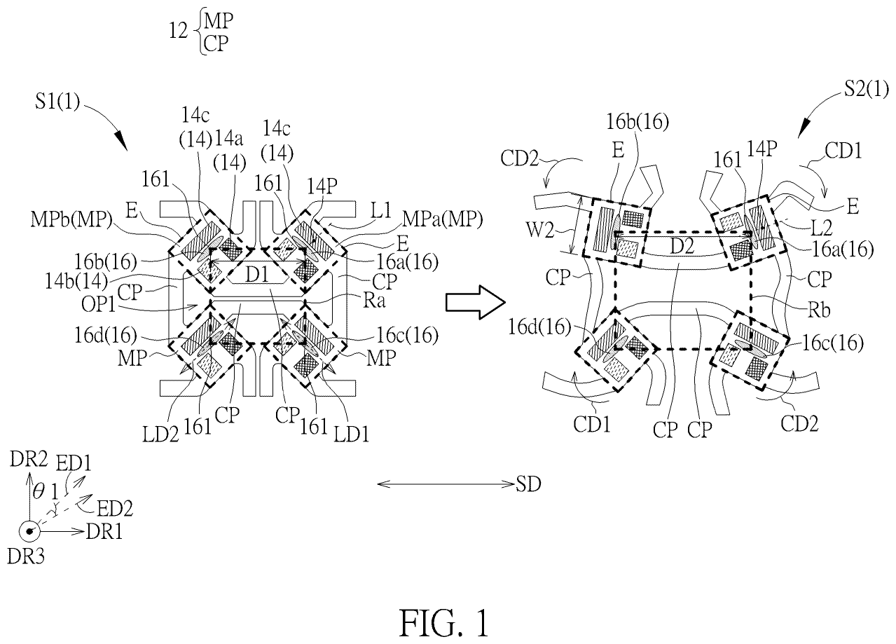

In the following figures, direction DR1, direction DR2, and direction DR3 are indicated. The direction DR3 may represent a normal direction or a normal direction of the electronic device. As shown in FIG. 1, the direction DR3 may be perpendicular to a top surface of a stretchable pattern substrate 12. The direction DR1 and the direction DR2 may be horizontal directions and may be perpendicular to the direction DR3. As shown in FIG. 1, the direction DR1 and the direction DR2 may be parallel to the top surface of the stretchable pattern substrate 12, and the direction DR1 and the direction DR2 may be perpendicular to each other. The spatial relationships of the structures in the following drawings may be described based on the direction DR1, the direction DR2, and the direction DR3.

Refer to FIG. 1, which schematically illustrates a top view of an electronic device operated in a first state and a second state according to a first embodiment of the present disclosure. As shown in FIG. 1, the electronic device 1 has the first state S1 and the second state S2. In other words, the electronic device 1 is able to be transformed from the first state S1 to the second state S2 or from the second state S2 to the first state S1. According to this embodiment, the electronic device 1 may, for example, be switched from the first state S1 to the second state S2 by stretching, but not limited thereto. The first state S1 shown in the left portion of FIG. 1 may be an unstretched state of the electronic device 1, and the second state S2 shown in the right portion of FIG. 1 may be a stretched state of the electronic device 1, but not limited thereto. The electronic device 1 may, for example, be extended from the first state S1 to the second state S2 along a stretched direction SD, but not limited thereto. In the present disclosure, the stretched direction SD may refer to a direction that the size of the electronic device 1 is macroscopically changed. Namely, the stretched direction SD may be, for example, a direction in which a force is applied to the electronic device 1, such that the size of the electronic device 1 is macroscopically changed in the direction. According to this embodiment, the stretched direction SD may be, for example, the direction DR1 and a direction opposite to the direction DR1. In some embodiments, the stretched direction SD is not limited to the direction shown in FIG. 1 and may be any other direction. In some embodiments, operating states of the electronic device 1 are not limited to the first state S1 and the second state S2 and may include other states.

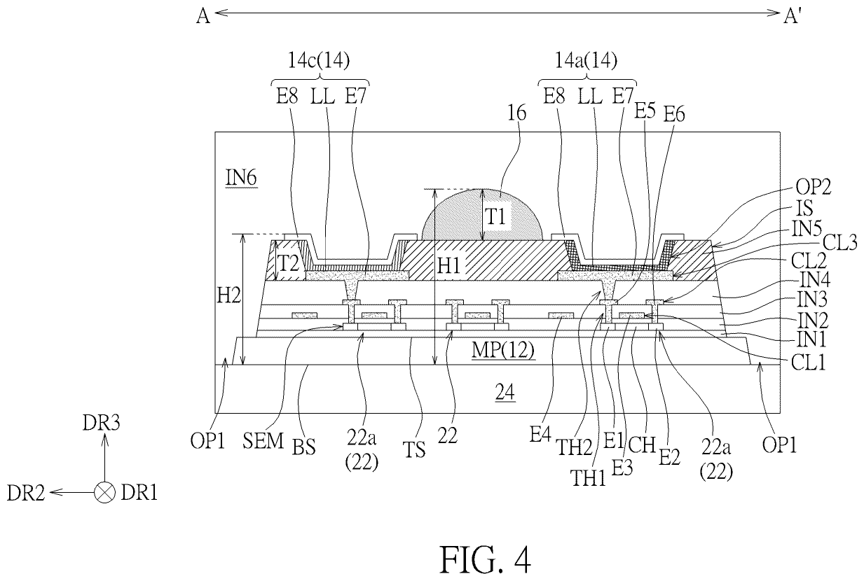

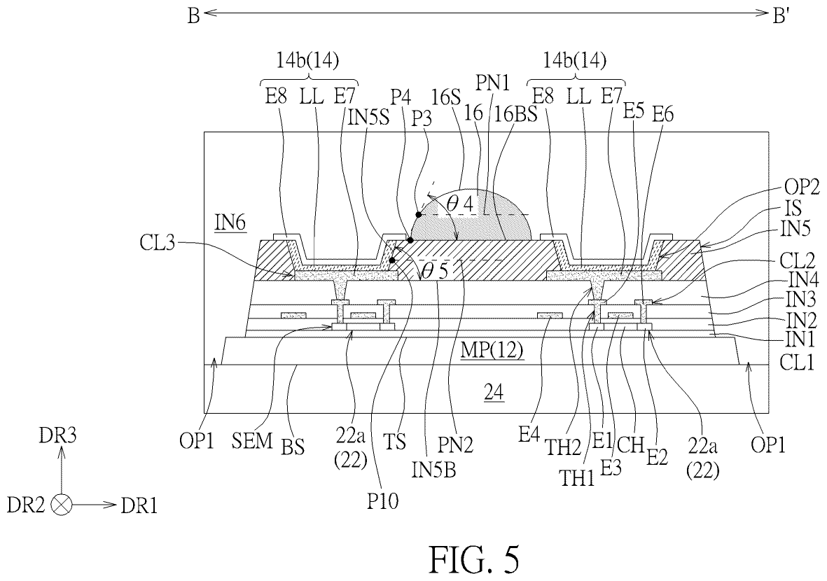

Specifically, the electronic device 1 includes a stretchable pattern substrate 12 having a stretchable characteristic, such that the state of the electronic device 1 is able to be changed. According to this embodiment, the stretchable pattern substrate 12 may include a plurality of portions MP and a plurality of connecting portions CP, wherein at least one of the connecting portions CP is connected between two adjacent portions MP. The portions MP may be configured to dispose electronic units (e.g., the electronic units 14 described below), an inorganic layer (e.g., the inorganic layers 18 described below), active elements, or other suitable elements, wherein the active element may include, but not limited to, a channel region of a transistor in a circuit layer (e.g., the channel region CH shown in FIG. 4 and FIG. 5). The connecting portion CP may be configured to vary a distance between two adjacent portions MP to which the connecting portion CP is connected. In other words, the portion MP may provide a supporting effect for the electronic unit disposed thereon, while the connecting portion CP may provide stretchable effect for the stretchable pattern substrate 12.

As shown in FIG. 1, each portion MP may be island-shaped and have an edge E that is connected to multiple connecting portions CP. In the present disclosure, the edge E of the portion MP may refer to an entire outer contour of the portion MP. For example, the portion MP may be rectangular, and the edge E may be formed by connecting four side edges, while the connecting portion CP may be strip-shaped, but not limited thereto. According to this embodiment, each portion MP may be connected to four connecting portions CP, but not limited thereto. Furthermore, a width of the side edge of the portion MP adjacent to one of the connecting portions CP connected thereto may be greater than a width of a part of the one of the connecting portions CP connected to the portion MP. In other words, the stretchable patterned substrate 12 may further include a plurality of openings OP1, each of which may be, for example, surrounded by four portions MP and four connecting portions CP connected alternately in sequence. When the electronic device 1 undergoes deformation (e.g., being stretched), the connecting portions CP may be deformed, and the sizes (e.g., length) of the connecting portions CP may be changed due to the deformation, thereby altering the distances between the adjacent portions MP connected to ends of the connecting portions CP. Alternatively, through different pattern configurations, the connecting portions CP may have different sizes to further vary the distances between adjacent portions MP. In some embodiments, the shapes of the portions MP may be adjusted according to the requirements.

The stretchable pattern substrate 12 may, for example, include a flexible substrate, or at least partially formed of a flexible substrate. The material of the stretchable pattern substrate 12 may include polyimide (PI), polycarbonate (PC), polyethylene terephthalate (PET), poly(methyl methacrylate) (PMMA), rubber, acrylonitrile butadiene styrene (ABS), auxetic material, or other suitable materials, or a combination of the aforementioned materials, wherein the auxetic material may include, for example, graphene or other suitable materials. The stretchable pattern substrate 12 may, for example, be a single-layer or a multilayer structure.

As shown in FIG. 1, the electronic device 1 may further include a plurality of electronic units 14 and a plurality of protruding units 16, wherein the electronic units 14 and the protruding units 16 may be disposed on corresponding portions MP, respectively. For example, the portions MP may include a portion MPa and a portion MPb, and the protruding units 16 may include a protruding unit 16a and a protruding unit 16b. Furthermore, one of the electronic units 14 and the protruding unit 16a may be disposed on the portion MPa, while another of the electronic units 14 and the protruding unit 16b may be disposed on the portion MPb, and one of the connecting portions CP is connected between the portion MPa and the portion MPb. According to this embodiment, multiple electronic units 14 and one of the protruding units 16 may be disposed on one of the portions MP, but not limited thereto. In some embodiments, at least one of the electronic units 14 and at least one of the protruding units 16 may be disposed on one of the portions MP.

The electronic unit 14 may include, for example, a chip, a light-emitting diode, a variable capacitor, a variable resistor, a varactor diode, other suitable electronic elements, or a combination thereof, but the present disclosure is not limited thereto. The light-emitting diode may include an organic light-emitting diode or an inorganic light-emitting diode. According to this embodiment, taking the organic light-emitting diode as an example of the electronic unit 14, the electronic device 1 may be, for example, a self-emissive display device, but not limited thereto. The electronic units 14 may include, for example, a plurality of electronic units 14a, a plurality of electronic units 14b, and a plurality of electronic units 14c, wherein the electronic units 14a, 14b, and 14c may respectively be used to emit light of different colors, such as red, green, and blue, but not limited thereto. In the embodiment shown in FIG. 1, one of the electronic units 14a, one of the electronic units 14b, and one of the electronic units 14c may be disposed on one of the portions MP and respectively serve as sub-pixels, such that the electronic units 14a, 14b, and 14c disposed on the same portion MP may form a pixel, but not limited thereto. In this case, the protruding unit 16 disposed on the same portion MP as the electronic units 14a, 14b, and 14c may be surrounded by the electronic units 14a, 14b, and 14c, but not limited thereto. In the present disclosure, the term that one element is “surrounded” by multiple elements may refer to the condition where the multiple elements are located on different sides of the element, without necessarily enclosing the element completely. In some embodiments, the numbers of electronic units 14a, 14b, and 14c disposed on the same portion MP may each be at least one, but not limited thereto.

The protruding unit 16 may have a supporting or positioning function. For example, the protruding unit 16 is used to support a mask for forming the electronic units 14 or to position the electronic units 14 during manufacturing processes, but not limited thereto. The protruding unit 16 may be located at a geometric center of the corresponding portion MP to provide better support for the mask used to form the electronic units 14, and may offer improved support in the case that the protruding unit 16 occupies minimal area of the portion MP, or provide enhanced positioning effect when transferring the electronic units 14 (i.e., positioning a region for disposing the electronic unit 14) through the protruding unit 16. The protruding unit 16 may include, for example, an organic material or other suitable materials, wherein the organic material may include a transparent organic material, a light-shielding material, or other suitable organic materials. The transparent organic material may include, for example, photosensitive polyimide (PSPI) or other suitable materials. When the protruding unit 16 includes the light-shielding material, stray light in the electronic device 1 may be reduced.

As shown in FIG. 1, when the electronic device 1 is in the first state S1, a distance D1 may be present between two adjacent protruding units 16 along the stretched direction SD. When the electronic device 1 is in the second state S2, another distance D2 may be present between the two adjacent protruding units 16 along the stretched direction SD, and the distance D1 is different from the distance D2. In the present disclosure, the distance between two adjacent protruding units 16 (e.g., the distance D1 or the distance D2) is obtained by measuring the distance between corresponding parts of the two protruding units 16. For example, the distance may be measured from the right side of one protruding unit 16 to the right side of the other protruding unit 16, or from a center point 161 of one protruding unit 16 to a center point 161 of the other protruding unit 16. According to this embodiment, when the electronic device 1 is extended from the first state S1 to the second state S2 along the stretched direction SD, the distance D2 may be greater than the distance D1, such that the size of the electronic device 1 in the stretched direction SD may be increased. For example, the distance D1 and the distance D2 may satisfy the following relationship: 1<D2/D1<2, so that the electronic device 1 may exhibit a noticeable change in size after being stretched, which is able to be easily recognized by the human eye.

In this embodiment, when the electronic device 1 is extended from the first state S1 to the second state S2 along the stretched direction SD, the distance between two adjacent protruding units 16 in the direction DR2 perpendicular to the stretched direction SD may also be increased, such that the size of the electronic device 1 in the direction DR2 may be increased. In other words, when the electronic device 1 is in the first state S1, connecting lines of center points 161 of four protruding units 16 may enclose a region Ra. When the electronic device 1 is extended to the second state S2, connecting lines of the center points 161 of the four protruding units 16 may enclose a region Rb, and the area of the region Rb is greater than that of the region Ra. In some embodiments, when the electronic device 1 is extended from the first state S1 to the second state S2 along the stretched direction SD, the size of the electronic device 1 in the direction DR2 may remain unchanged or slightly be decreased according to the requirements. In some embodiments, the area A1 of the region Ra and the area A2 of the region Rb may satisfy the following relationship: 1<A2/A1<4.

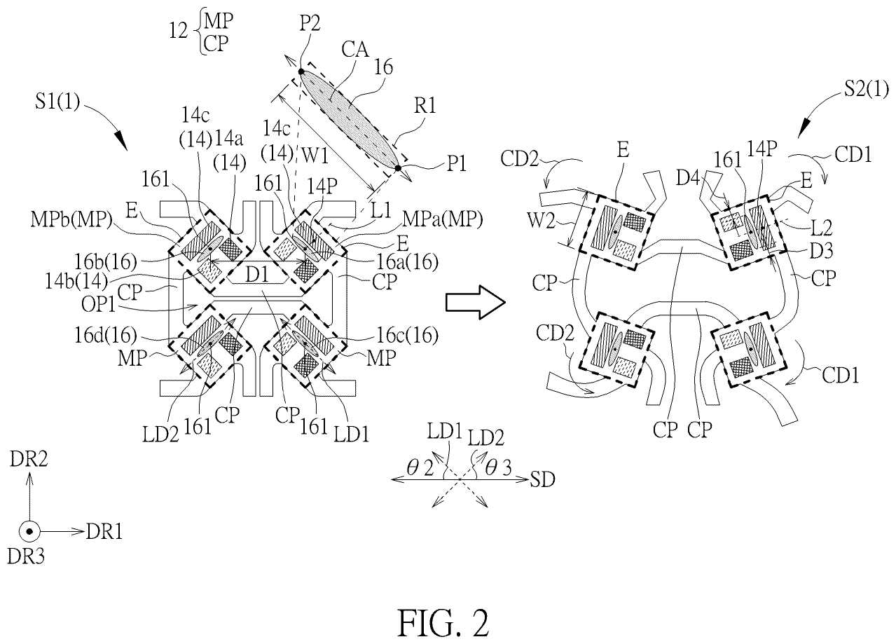

As shown in the second state S2 at the right side of FIG. 1, when the electronic device 1 is extended from the first state S1 to the second state S2 along the stretched direction SD, the adjacent protruding units 16 (e.g., the protruding unit 16a and protruding unit 16b arranged along the direction DR1) may be different in direction of rotation. For example, when the electronic device 1 is extended from the first state S1 to the second state S2, the protruding unit 16a may rotate in a clockwise direction CD1, while the protruding unit 16b may be rotated in a counterclockwise direction CD2. Furthermore, the protruding unit 16d, which is arranged along the direction DR2 with the protruding unit 16b, may be rotated in the clockwise direction CD1 when the electronic device 1 is extended from the first state S1 to the second state S2. In the present disclosure, the clockwise direction CD1 and the counterclockwise direction CD2 are determined based on a right-hand rule. When a right thumb points in the normal direction of the electronic device 1 (e.g., the direction DR3), the direction in which right four fingers curl serves as the counterclockwise direction CD2, and a direction opposite to the direction in which right four fingers curl serves as the clockwise direction CD1. Alternatively, the stresses on different connecting portions CP connected to the same portion MP applied by the same external force may be adjusted to be different, such that some of adjacent portions MP may be the same in direction of rotation, for example, being rotated simultaneously in the clockwise direction CD1 or the counterclockwise direction CD2, when being switched from the first state S1 to the second state S2. As shown in FIG. 2, in a variant embodiment, when the electronic device 1 is extended from the first state S1 to the second state S2 along the stretched direction SD, adjacent protruding units 16 may be the same in direction of rotation. For example, the protruding units 16b and 16d, which are arranged in the direction DR2 perpendicular to the stretched direction SD and adjacent to each other, may both be rotated in the counterclockwise direction CD2 when the electronic device 1 is extended from the first state S1 to the second state S2, or the protruding units 16a and 16c may both be rotated in the clockwise direction CD1. In some embodiments, when the electronic device 1 is extended from the first state S1 to the second state S2 along the stretched direction SD, some portions MP may not be rotated.

According to this embodiment, as shown in FIG. 1, when the electronic device 1 is extended from the first state S1 to the second state S2 along the stretched direction SD, a rotation angle θ1 of the protruding unit 16 relative to the electronic unit 14 may be greater than 0. Taking the protruding unit 16a and the corresponding electronic unit 14c as an example, a virtual line L1 may be formed between the center point 161 of the protruding unit 16a and the center point 14P of the electronic unit 14c in the first state S1, and a virtual line L2 may be formed between the center point 161 of the protruding unit 16a and the center point 14P of the electronic unit 14c in the second state S2. When the virtual line L1 is not parallel to the virtual line L2, it indicates that the rotation angle θ1 is greater than 0. Furthermore, an angle between an extending direction ED1 of the virtual line L1 and an extending direction ED2 of the virtual line L2 may be the rotation angle θ1. The rotation angle θ1 may be, for example, greater than 0 degrees and less than or equal to 45 degrees (i.e., 0°<θ1≤45°). The term “extending direction of the virtual line” may refer to a direction from the center point 161 of the protruding unit 16 toward the center point 14P of the electronic unit 14, but not limited thereto.

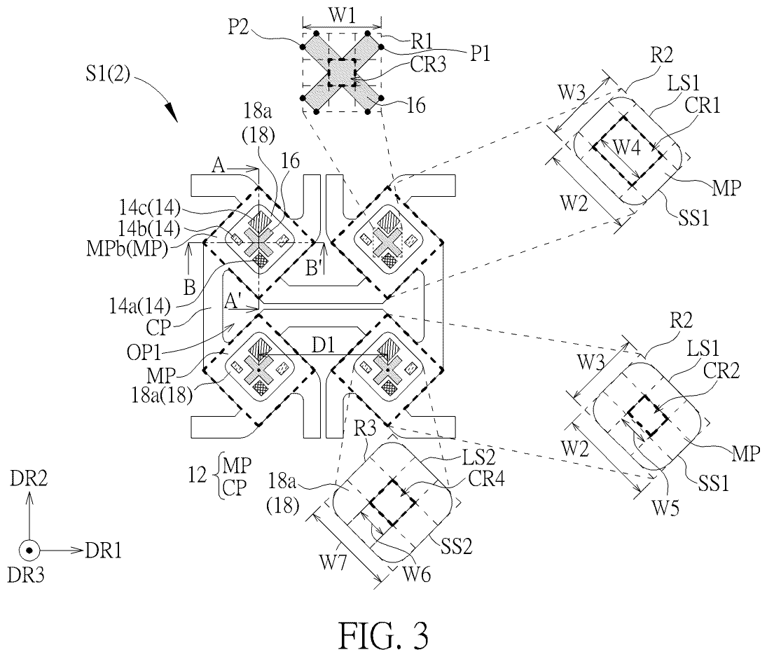

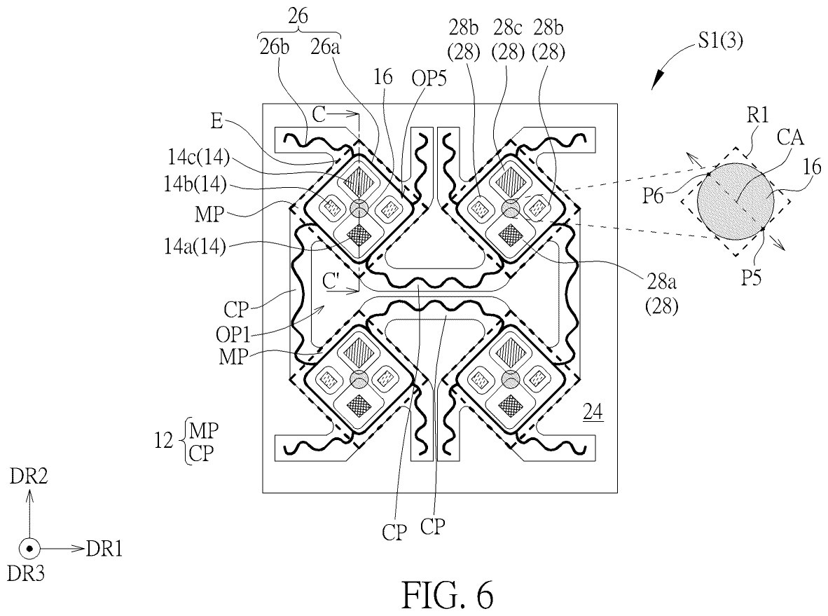

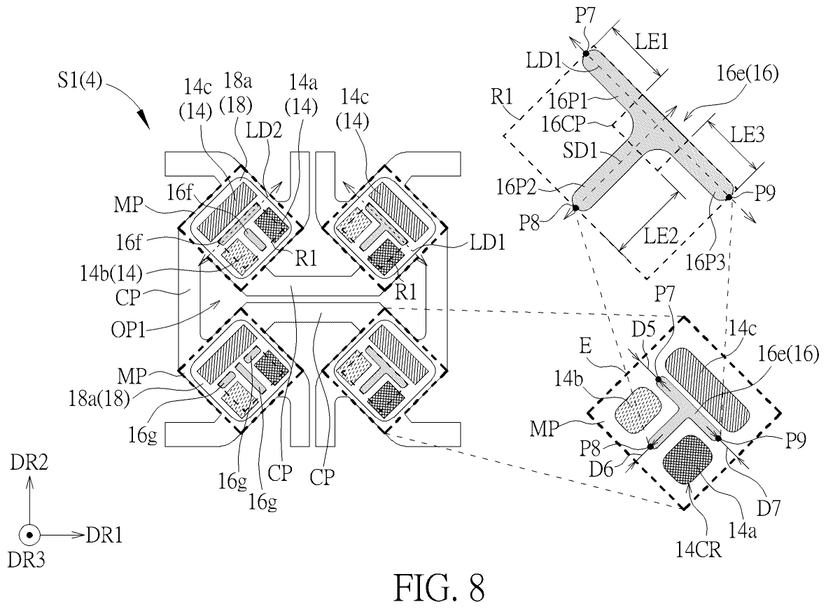

To clearly illustrate the electronic device 1, some reference numerals of the electronic device 1 are shown in FIG. 2, but not limited to those shown in FIG. 1. As shown in FIG. 2, in some embodiments, when the electronic device 1 is in the first state S1, adjacent protruding units 16 are respectively disposed along longitudinal directions that are not parallel to each other. For example, as shown in FIG. 2, the protruding unit 16c is arranged along a longitudinal direction LD1, and the protruding unit 16d is arranged along a longitudinal direction LD2 that is not parallel to the longitudinal direction LD1. The term “longitudinal direction” may refer to a direction along or parallel to a long axis of an object. The long axis may be a line that longitudinally extends through the center of the object. In FIG. 2, taking the elliptical protruding unit 16 as an example, the long axis approximately corresponds to the maximum size of the ellipse in the longitudinal direction. For instance, the protruding unit 16 may have end points P1 and P2, and may further include a central axis CA, where the central axis CA is parallel to the longitudinal direction and passes through the end points P1 and P2, but not limited thereto. In some embodiments, for objects that do not have an obvious long axis or have irregular shapes, the long axis may be defined as a long axis of a minimum rectangle R1 that is able to enclose the object, and the longitudinal direction may be a direction parallel to a long side of the minimum rectangle R1. For example, as shown in an enlarged view of the protruding unit 16 at the upper left side of FIG. 2, the protruding unit 16 may be enclosed by a minimum rectangle R1, such that the minimum rectangle R1 is able to cover the entire protruding unit 16, and the direction along or parallel to the long side of the rectangle R1 is the longitudinal direction. The minimum rectangle R1 may be obtained using software such as OpenCV or other suitable software. In some embodiments, the top-view shape of the protruding unit 16 may be, for example, triangular, circular (e.g., as shown in FIG. 6), T-shaped (e.g., as shown in FIG. 8), X-shaped (e.g., as shown in FIG. 3), rectangular, polygonal, L-shaped, irregular, or other suitable shapes. In some embodiments, when the minimum rectangle R1 is a square, the longitudinal direction may be, for example, a direction parallel to any side of the minimum rectangle R1.

In some embodiments, when the electronic device 1 is extended from the first state S1 to the second state S2 along the stretched direction SD, an acute angle θ2 between the longitudinal direction LD1 and the stretched direction SD may be different from an acute angle θ3 between the longitudinal direction LD2 and the stretched direction SD, but not limited thereto. In some embodiments, when the longitudinal direction LD1 is not parallel to the longitudinal direction LD2, the acute angle θ2 may alternatively be equal to the acute angle θ3.

In some embodiments, the protruding unit 16 has a maximum width W1, and the distance D1 may be greater than the maximum width W1, such that the protruding units 16 located on different portions MP have a relatively large distance between them to reduce the difficulty of structural design, and the electronic device 1 may exhibit the noticeable change in size after being stretched from the first state S1 to the second state S2. In the present disclosure, the maximum width W1 of the protruding unit 16 refers to the maximum width of the minimum rectangle R1 that encloses the protruding unit 16, wherein the maximum width of the minimum rectangle R1 refers to the width of its longest side, i.e., the width of its long side. In some embodiments, the distance D1 may be greater than the maximum width W2 of the portion MP, wherein the maximum width W2 of the portion MP in the present disclosure may alternatively refer to the maximum width of a minimum rectangle (e.g., the minimum rectangle R3 described below) that encloses the portion MP, i.e., the width of the long side of the minimum rectangle, which reference may be made to the below description and will not be repeated here.

In some embodiments, a minimum distance D3 may be present between the protruding unit 16 and an edge E of the corresponding portion MP in a direction, and the minimum distance D3 and the maximum width W1 may satisfy the following relationship: 0<D3≤W1. For example, the minimum distance D3 may be greater than or equal to 0.01 micrometers (μm). It should be noted that when the minimum distance D3 between the protruding unit 16 and the edge E (or an opening OP1) of the portion MP becomes smaller, it may lead to poor yield in the quality of the protruding unit 16 during manufacturing. On the other hand, as the minimum distance D3 becomes larger, the supporting effect of the protruding unit 16 may be adversely affected. Therefore, with the minimum distance D3 satisfying the above relationship, the supporting effect of the protruding unit 16 may be enhanced while maintaining a certain yield of the protruding unit 16. In some embodiments, the minimum distance D3 between the end point P1 and the edge E of the portion MP may be the same as or different from another minimum distance D4 between the end point P2 and the edge E of the portion MP, but not limited thereto.

In some embodiments, the maximum width W1 of the protruding unit 16 may be greater than or equal to 0.3 times the maximum width W2 of the portion MP, such that the protruding unit 16 has sufficient or improved support. Furthermore, when the protruding unit 16 is too close to the edge E of the portion MP, it may easily result in poor yield of the protruding unit 16. With the maximum width W1 of the protruding unit 16 being less than or equal to 0.98 times the maximum width W2 of the portion MP, the yield issue may be improved. For example, the maximum width W1 may be greater than or equal to 0.3 times and less than or equal to 0.98 times the maximum width W2 of the portion MP (i.e., 0.3 W2≤W1≤0.98W2). Alternatively, the maximum width W1 may be greater than or equal to 0.6 times and less than or equal to 0.9 times the maximum width W2 of the portion MP (i.e., 0.6W2≤W1≤0.9W2), but not limited thereto.

In some embodiments, the electronic device 1 may further include a plurality of connecting wires disposed on the stretchable pattern substrate 12 and used to electrically connect electronic units 14 and/or active elements disposed on two adjacent portions MP. Specifically, at least one connecting wire may be disposed on the two adjacent portions MP and the connecting portion CP connected therebetween, but not limited thereto.

The electronic device of the present disclosure is not limited to the above embodiments and may include other variant embodiments or other embodiments. For simplicity, the following variant embodiments or other embodiments will use the same reference numerals to denote the same elements as in the above embodiments. To facilitate comparison between the above embodiment and the variant embodiments or other embodiments, the following description will mention the differences between the embodiments, and repeated parts will not be redundantly described.

Refer to FIG. 3, which schematically illustrates a top view of the electronic device operated in the first state according to a second embodiment of the present disclosure. In the electronic device 2 provided in this embodiment, the top-view shape of the protruding unit 16 in FIG. 3 takes an X-shape as an example, but not limited thereto. In some embodiments, the top-view shape of the protruding unit 16 may alternatively be any of the shapes described above. According to this embodiment, the number of the electronic units 14 disposed on the same portion MP may be, for example, four, which helps dispose the corresponding protruding unit 16 on the same portion MP, but not limited thereto. In this case, a part of the protruding unit 16 may be disposed between any two adjacent electronic units 14. For example, the electronic units 14 disposed on the same portion MP may include one electronic unit 14a, two electronic units 14b, and one electronic unit 14c to form a pixel, but not limited thereto. In some embodiments, the configuration of the electronic units 14 disposed on the same portion MP in FIG. 3 may alternatively adopt the configuration of the embodiments shown in FIG. 1 or FIG. 2, or other suitable configurations, but not limited thereto.

According to this embodiment, the protruding unit 16 may at least partially overlap a central region CR1 of the portion MP, such that the protruding unit 16 may provide a certain supporting effect. Furthermore, as shown in the enlarged schematic view of the portion MP at the upper right side of FIG. 3, the portion MP may be enclosed by a minimum rectangle R2. For example, calculated from a short side SS1 of the minimum rectangle R2, the central region CR1 may be located in a range from 0.2 times to 0.8 times the maximum width W2 of the long side LS1, and calculated from the long side LS1 of the minimum rectangle R2, the central region CR1 may be located in a range from 0.2 times to 0.8 times the width W3 of the short side SS1. In other words, a distance between the central region CR1 and any long side LS1 of the minimum rectangle R2 may be 0.2 times the width W3 of the short side SS1, and the distance between the central region CR1 and any short side SS1 of the minimum rectangle R2 may be 0.2 times the maximum width W2 of the long side LS1. In this case, the long side width of the central region CR1 may be, for example, 0.6 times the maximum width W2 of the long side LS1 of the minimum rectangle R2, and the short side width of the central region CR1 may be, for example, 0.6 times the width W3 of the short side SS1 of the minimum rectangle R2. In this embodiment, the maximum width W4 of the central region CR1 may be the long side width of the central region CR1, but not limited thereto. In some embodiments, when the minimum rectangle R2 is a square, the central region CR1 may be a square, and its maximum width W4 may be the width of any of its sides. In some embodiments, the structure in which the protruding unit 16 at least partially overlaps the central region CR1 may alternatively be applicable to any of the embodiments described above or below.

In some embodiments, the protruding unit 16 may be enclosed by the minimum rectangle R1, and the maximum width W1 of the minimum rectangle R1 may be greater than or equal to the maximum width W5 of another central region CR2 of the portion MP, such that the protruding unit 16 has better supporting effect and provides improved support while occupying minimal area. The end points P1 and P2 of the protruding unit 16 may, for example, be located at the corners of the X-shape. Furthermore, as shown in the enlarged schematic view of the portion MP at the lower right side of FIG. 3, calculated from the short side SS1 of the minimum rectangle R2, the central region CR2 may be located in a range from 0.33 times to 0.67 times the maximum width W2 of the long side LS1, and calculated from the long side LS1 of the minimum rectangle R2, the central region CR2 may be located in a range from 0.33 times to 0.67 times the width W3 of the short side SS1. In other words, the distance between the central region CR2 and any long side LS1 of the minimum rectangle R2 may be one-third of the width W3 of the short side SS1, and the distance between the central region CR2 and any short side SS1 of the minimum rectangle R2 may be one-third of the maximum width W2 of the long side LS1. In this case, the long side width of the central region CR2 may be one-third of the maximum width W2 of the long side LS1 of the minimum rectangle R2, and the short side width of the central region CR2 may be one-third of the width W3 of the short side SS1 of the minimum rectangle R2, wherein the long side width and short side width of the central region CR2 may be greater than 0, and the maximum width W5 of the central region CR2 may be its long side width. In some embodiments, when the minimum rectangle R2 is a square, the central region CR2 may be a square, and its maximum width W5 may be the width of any of its sides. In some embodiments, the structure in which the maximum width W1 is greater than or equal to the maximum width W5 may alternatively be applicable to any of the embodiments described above or below.

In some embodiments, the minimum rectangle R1 may further include a central region CR3, and a part of the protruding unit 16 located within the central region CR3 may overlap the central region CR2 of the minimum rectangle R2, thereby enhancing the supporting effect of the protruding unit 16 and providing improved support while occupying minimal area. In some embodiments, the structure in which the part of the protruding unit 16 located within the central region CR3 overlap the central region CR2 may alternatively be applicable to any of the embodiments described above or below.

According to this embodiment, the electronic device 1 may further include an inorganic layer 18 disposed on the portion MP. As shown in FIG. 3, the inorganic layer 18 may include a plurality of inorganic islands 18a, which are respectively disposed on corresponding portions MP and are separated from each other. Since the inorganic layer 18 includes an inorganic insulating material and has relatively high stress, it cannot withstand repeated stretching. Therefore, by separating the inorganic islands 18a from each other and respectively disposing them on the portions MP, damage to the inorganic layer 18 during switching states may be reduced. The inorganic layer 18 of this embodiment may be applicable to any of the embodiments described above or below.

As shown in FIG. 3, the protruding unit 16 may overlap a central region CR4 of the inorganic island 18a, such that the protruding unit 16 may provide better support while occupying minimal area. In this case, the maximum width W1 of the protruding unit 16 may, for example, be greater than or equal to the maximum width W6 of the central region CR4 of the inorganic island 18a. Specifically, as shown in the enlarged schematic view of the inorganic island 18a at the lower side of FIG. 3, the inorganic island 18a may be enclosed by a minimum rectangle R3, and the minimum rectangle R3 may include a central region CR4. Calculated from a short side SS2 of the minimum rectangle R3, the central region CR4 may be located within a range from 0.33 times (or one-third) to 0.67 times (or two-thirds) the maximum width W7 of the long side LS2 of the minimum rectangle R3, and calculated from a long side LS2 of the minimum rectangle R3, the central region CR4 may be located within a range from 0.33 times (or one-third) to 0.67 times (or two-thirds) the width of the short side SS2. In other words, the distance between the central region CR4 and any long side LS2 of the minimum rectangle R3 may be one-third of the width of the short side SS2, and the distance between the central region CR4 and any short side SS2 of the minimum rectangle R3 may be one-third of the maximum width W7 of the long side LS2. The maximum width W6 of the central region CR4 may be the width of its long side and is greater than 0. In some embodiments, when the maximum width W1 is greater than or equal to the maximum width W6, the maximum width W7 of the minimum rectangle R3 may further be greater than or equal to the maximum width W1 of the protruding unit 16, and/or the maximum width W7 of the minimum rectangle R3 may be less than or equal to the maximum width W2 of the minimum rectangle R2 (i.e., 0<W6≤W1≤W7≤W2). In some embodiments, the structure in which the protruding unit 16 overlaps the central region CR4 of the inorganic island 18a, and/or the relationships among the maximum width W1, maximum width W6, maximum width W7, and maximum width W2 may alternatively be applicable to any of the embodiments described above or below.

Refer to FIG. 4 and FIG. 5, wherein FIG. 4 schematically illustrates a cross-sectional view of FIG. 3 taken along a cross-sectional line A-A′, and FIG. 5 schematically illustrates a cross-sectional view of FIG. 3 taken along a cross-sectional line B-B′. As shown in FIG. 4, the protruding unit 16 may be higher than the electronic unit 14 in the normal direction of the electronic device 2 (e.g., the direction DR3). As mentioned herein, an element “higher than” another element refers to a comparison of the distances of the top surface of the element and the top surface of the another element relative to the same reference plane. For example, when the top surface of the protruding unit 16 is curved, the height H1 of the protruding unit 16 may refer to the height of the apex of the top surface of the protruding unit 16, that is, the distance between the apex of the top surface of the protruding unit 16 and the bottom surface BS of the stretchable pattern substrate 12, while the height H2 of the electronic unit 14 may refer to the distance between a top surface of the electronic unit 14 and the bottom surface BS of the stretchable pattern substrate 12, wherein the height H1 of the protruding unit 16 may be greater than the height H2 of the electronic unit 14.

As shown in FIG. 4 and FIG. 5, the electronic device 2 may further include a plurality of insulating layers disposed on the stretchable pattern substrate 12. At least one of the insulating layers may include an inorganic insulating material and serve as the inorganic layer 18 shown in FIG. 3. According to this embodiment, the insulating layers may include, for example, insulating layers IN1, IN2, IN3, IN4, and IN5, wherein the insulating layer IN1 may include a multilayer structure, and the multilayer structure may include a stack of an inorganic material layer and an organic material layer. In other words, since the insulating layer IN1 includes the inorganic insulating material, it may serve as at least a portion of the inorganic layer 18 shown in FIG. 3, and the edge of the inorganic layer 18 may be defined by the edge of the insulating layer IN1, but not limited thereto. In some embodiments, the number of insulating layers may be adjusted according to the requirements.

In this embodiment, the electronic device 2 may include a plurality of island structures IS respectively corresponding to the inorganic islands 18a shown in FIG. 3, such that the island structures IS may be respectively disposed on the corresponding portions MP of the stretchable pattern substrate 12. For clarity, FIG. 4 and FIG. 5 show one island structure IS, but are not limited thereto. As shown in FIG. 4 and FIG. 5, the island structure IS may include a portion of the insulating layer IN1, a portion of the insulating layer IN2, a portion of the insulating layer IN3, a portion of the insulating layer IN4, and a portion of the insulating layer IN5, and in the island structure IS, the insulating layers IN1, IN2, IN3, IN4, and IN5 may be sequentially disposed on the corresponding portion MP.

According to this embodiment, the electronic device 2 may further include a plurality of transistors 22 disposed on the insulating layer IN1, and at least one of the transistors 22 may be electrically connected to at least one of the electronic units 14 and serve as a driving element and/or switching element of the corresponding electronic unit 14, but not limited thereto. For example, the transistors 22 may include a transistor 22a electrically connected to the corresponding electronic unit 14.

In this embodiment, the insulating layer IN1 may serve, for example, as a buffer layer to reduce the possibility of damage to the transistors 22 and/or the electronic units 14 caused by moisture and/or oxygen passing through the stretchable pattern substrate 12. The transistor 22 shown in FIG. 4 and FIG. 5 takes a top-gate thin-film transistor as an example, but not limited thereto. In this case, the island structure IS may further include a semiconductor layer SEM, a conductive layer CL1, a conductive layer CL2, and a conductive layer CL3, wherein the semiconductor layer SEM is disposed on the insulating layer IN1 and includes a plurality of semiconductors. Two end portions of each semiconductor include doped regions serving respectively as a source (drain) electrode E1 and a drain (source) electrode E2 of the transistor 22, and a portion of the semiconductor located between the source (drain) electrode E1 and the drain (source) electrode E2 may serve as a channel region CH of the transistor 22. The material of the semiconductor layer SEM may include, for example, silicon or metal oxide, such as low-temperature poly-silicon (LTPS) semiconductor, amorphous silicon (a-Si) semiconductor, indium gallium zinc oxide (IGZO) semiconductor, or other suitable semiconductors, but not limited thereto.

The insulating layer IN2 is disposed on the semiconductor layer SEM and the insulating layer IN1 and serves as a gate insulating layer of the transistor 22. The conductive layer CL1 is disposed on the insulating layer IN2 and may include a plurality of electrodes E3, which are disposed corresponding to the channel regions CH and serve as gate electrodes of the transistors 22, respectively. In some embodiments, the conductive layer CL1 may optionally include a plurality of electrodes E4, signal lines (e.g., scan lines), or other conductive elements, but not limited thereto.

The insulating layer IN3 is disposed on the conductive layer CL1 and the insulating layer IN2, and the conductive layer CL2 is disposed on the insulating layer IN3. The insulating layers IN2 and IN3 may include a plurality of through holes TH1, which respectively correspond to the source (drain) electrodes E1 and the drain (source) electrodes E2 of the transistors 22. The conductive layer CL2 may include a plurality of electrodes E5 and a plurality of electrodes E6, which are respectively disposed in the corresponding through holes TH1, such that the electrodes E5 and E6 may be electrically connected to the source (drain) electrodes E1 and the drain (source) electrodes E2 of the transistors 22, respectively.

The insulating layer IN4 is disposed on the insulating layer IN3 and the conductive layer CL2 and includes a plurality of through holes TH2 corresponding to the electrodes E5, respectively. The electronic unit 14 may be disposed on the insulating layer IN4 and electrically connected to the corresponding electrode E5 through the through hole TH2, so as to be electrically connected to the corresponding transistor 22a. In some embodiments, the conductive layer CL2 may optionally include electrodes, signal lines (e.g., data lines), or other conductive elements, but not limited thereto. The conductive layers CL1, CL2, and CL3 may each include metal or other suitable conductive materials.

The insulating layer IN5 is disposed on the insulating layer IN4 and includes a plurality of openings OP2. The electronic units 14 are respectively disposed corresponding to the openings OP2. For example, the openings OP2 may be used to define the positions of pixels or sub-pixels of the electronic device 2, and the insulating layer IN5 may be referred to as a pixel defining layer, but not limited thereto. The insulating layer IN5 may include, for example, a transparent insulating material, a light-blocking material, or other suitable materials. In this embodiment, as shown in FIG. 4, the protruding unit 16 may be disposed on the insulating layer IN5, wherein in the normal direction (e.g., the direction DR3), the thickness T1 of the protruding unit 16 may be greater than or equal to the thickness T2 of the insulating layer IN5, and the thickness T2 of the insulating layer IN5 is greater than 0 (i.e., 0<thickness T2≤thickness T1), but not limited thereto. The thickness T1 of the protruding unit 16 may refer to the maximum thickness of the protruding unit 16 in the normal direction, and the thickness T2 of the insulating layer IN5 may refer to the maximum thickness of the insulating layer IN5 in the normal direction. For example, the thickness T1 may be 1.28 μm, and the thickness T2 may be 0.9 μm.

According to this embodiment, as shown in FIG. 4 and

FIG. 5, the electronic unit 14 may include a bottom electrode E7, a light-emitting layer LL, and a top electrode E8, wherein the bottom electrode E7 is disposed between the insulating layer IN4 and the insulating layer IN5 and corresponds to the opening OP2, and the bottom electrode E7 may be electrically connected to the electrode E5 through the through hole TH2. The light-emitting layer LL is disposed within the corresponding opening OP2, and the top electrode E8 is disposed on the corresponding light-emitting layer LL and the insulating layer IN5. In this embodiment, the top electrodes E8 of different electronic units 14 may, for example, be connected to each other at a position where is not overlapped with the protruding unit 16 to form a common electrode, but not limited thereto.

In this embodiment, the electronic device 2 may further include an insulating layer IN6, which may be disposed on the electronic units 14 and cover the electronic units 14 to protect the electronic units 14, the transistors 22, wires, and/or other elements of the electronic device 2, but not limited thereto. In this embodiment, the insulating layer IN6 may be disposed between two adjacent island structures IS, and the insulating layer IN6 may be disposed in the openings OP1. The insulating layer IN6 may serve, for example, as an encapsulation layer. The insulating layer IN6 may include any suitable organic insulating material, such as PMMA, epoxy, siloxane material, silica gel material, other suitable passivation materials, or a combination thereof, but not limited thereto.

In some embodiments, the insulating layers IN5, IN4, IN3, IN2, and IN1 may include a single-layer structure or a multilayer structure, and may include any suitable organic or inorganic material. The organic material may include, for example, PMMA, epoxy, siloxane material, silica gel material, other suitable materials, or a combination thereof. The inorganic material may include silicon nitride, silicon oxide, silicon oxynitride, liquid glass, glass glue, titanium oxide, aluminum oxide, other suitable materials, or a combination thereof. In some embodiments, when the insulating layers IN5, IN4, IN3, IN2, and IN1 are multilayer structures, each of them may include a stacked structure of multiple inorganic material layers or multiple organic material layers, or an alternately stacked structure of inorganic/organic material layers, but the present disclosure is not limited thereto.

According to this embodiment, as shown in FIG. 5 in a cross-sectional view, an acute angle θ4 between a side 16S of the protruding unit 16 and a surface (e.g., a top surface TS) of a portion MP is less than an acute angle θ5 between a side of the insulating layer IN5 (e.g., a sidewall of the opening OP2) and a surface of the portion MP. For example, the acute angle θ4 is greater than or equal to 0 degrees and less than or equal to the acute angle θ5, and the acute angle θ5 is less than or equal to 90 degrees (i.e., 0°≤θ4≤θ5≤90°). In the present disclosure, the term “acute angle” refers to an angle measured based on an intersection point between a side of the corresponding element and a plane located at 50% of the thickness of the element. In this embodiment, the side 16S may be, for example, a curved surface, but not limited thereto. In this case, the side 16S of the protruding unit 16 may have an intersection point P3 with a plane PN1 located at half the thickness of the protruding unit 16 in the cross-sectional view, and the side 16S of the protruding unit 16 may have a junction point P4 connected to a bottom surface 16BS of the protruding unit 16. The acute angle θ4 may be defined as an angle between a connecting line of the intersection point P3 and the junction point P4 and a plane parallel to the bottom surface 16BS of the protruding unit 16 (e.g., the top surface TS of the portion MP), but not limited thereto. In addition, the side IN5S of the insulating layer IN5 may be, for example, a planar surface, and may have an intersection point P10 with a plane PN2 located at half the thickness of the insulating layer IN5. The acute angle θ5 is defined as an angle between a plane of the side IN5S of the insulating layer IN5 at the intersection point P10 and a plane parallel to the bottom surface IN5B of the insulating layer IN5 (e.g., the top surface TS of the portion MP), but not limited thereto.

In some embodiments, as shown in FIG. 4 and FIG. 5, the electronic device 2 may further include a flexible substrate 24 disposed on a bottom surface BS of the stretchable pattern substrate 12 to protect the stretchable pattern substrate 12. The flexible substrate 24 may be, for example, a non-pattern substrate and may be overlapped with the openings OP1 of the stretchable pattern substrate 12 in the direction DR3. The flexible substrate 24 may include, for example, PI, PC, PET, PMMA, rubber, ABS resin, other suitable materials, or any combination thereof. The cross-sectional structure of the electronic device 2 shown in FIG. 4 and FIG. 5 may alternatively be applicable to the electronic device 1 shown in FIG. 1. Other portions of the electronic device 2 in this embodiment may be the same as or similar to those of the electronic device 1 shown in FIG. 1 or FIG. 2, and thus reference may be made to the above descriptions, which will not be repeated here.

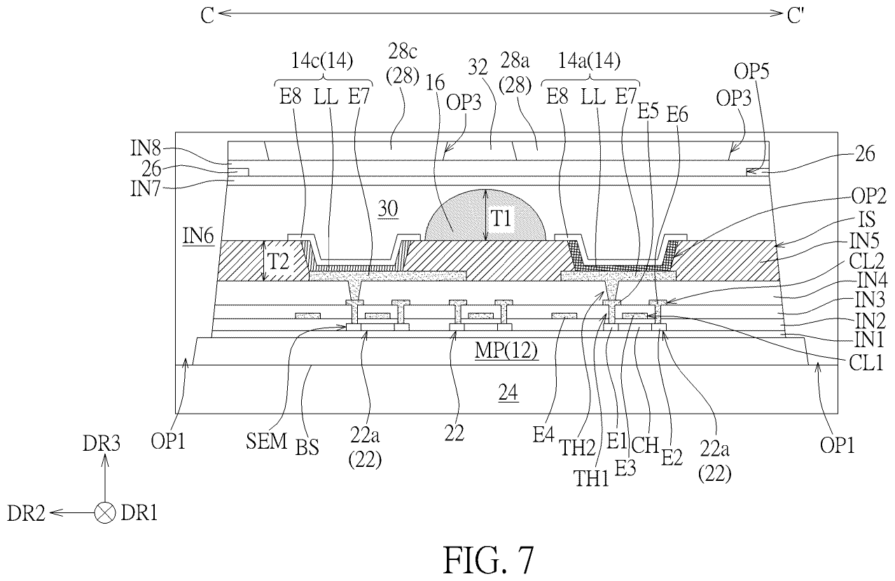

Refer to FIG. 6 and FIG. 7. FIG. 6 schematically illustrates a top view of an electronic device operated in the first state according to a third embodiment of the present disclosure, and FIG. 7 schematically illustrates a cross-sectional view taken along a cross-sectional line C-C′ of FIG. 6. One of main differences between the electronic device 3 provided in this embodiment and the electronic device 2 shown in FIG. 3 is that the electronic device 3 may further include a sensing electrode 26 disposed on the portions MP, wherein the sensing electrode 26 surrounds the electronic units 14 and the protruding unit 16. In other words, the sensing electrode 26 has openings OP5, and the electronic units 14a, 14b, and 14c and the protruding unit 16 disposed on the same portion MP are located within the corresponding opening OP5. According to this embodiment, the sensing electrode 26 may include a plurality of ring portions 26a and a plurality of connecting portions 26b, wherein the ring portions 26a may be respectively disposed on corresponding portions MP, and the connecting portions 26b may be disposed on the connecting portions CP to electrically connect the ring portions 26a disposed on two adjacent portions MP. In FIG. 6, at least one electronic unit 14 may be located between the ring portion 26a and the protruding unit 16, but not limited thereto. It should be noted that, since the sensing electrode 26 and the protruding unit 16 do not overlap each other in the top view, the influence of surface unevenness caused by the protruding unit 16 on the quality of the sensing electrode 26 may be reduced. In this embodiment, the sensing electrode 26 represents a sensing element, but the structure of the sensing element is not limited to that shown in FIG. 6 and FIG. 7. The sensing element may include touch sensing, biosensing, distance sensing, electromagnetic wave sensing, or other suitable sensing applications. The sensing electrode 26 may include a conductive material, such as metal or other suitable conductive materials. In some embodiments, the ring portion 26a may not be a fully closed structure surrounding the electronic units 14 and the protruding unit 16, and may have an open segment or partially surround the electronic units 14 and the protruding unit 16.

As shown in FIG. 7, the electronic device 3 may further include a protective layer 30 disposed on the electronic unit 14, the protruding unit 16, and the insulating layer IN5 to reduce the possibility of damage to the electronic unit 14 caused by moisture or oxygen. The electronic device 3 may optionally further include an insulating layer IN7 disposed between the protective layer 30 and the sensing electrode 26, such that the stack of the protective layer 30 and the insulating layer IN7 may help planarize its top surface. The protective layer 30 and the insulating layer IN7 may include, for example, a stack of at least one inorganic material layer and at least one organic material layer, or multiple inorganic material layers, but the present disclosure is not limited thereto. The inorganic material layer may include, for example, silicon nitride, silicon oxide, silicon oxynitride, aluminum oxide, or other suitable protective materials, or any combination of the aforementioned inorganic materials. Different inorganic material layers may include the same or different materials. The organic material layer may have an effect of planarizing its top surface, and may include, for example, resin or other suitable materials, but not limited thereto.

In some embodiments, the electronic device 3 may optionally further include an insulating layer IN8 disposed on the sensing electrode 26 to protect the sensing electrode 26. The insulating layer IN8 may include, for example, a single-layer structure or multilayer structure, and may include any suitable organic or inorganic materials as described above. At least one of the sensing electrode 26, the protective layer 30, the insulating layer IN7, and the insulating layer IN8 in this embodiment may be applicable to any of the embodiments described above or below.

As shown in FIG. 6 and FIG. 7, the electronic device 3 may optionally further include an optical element 28 disposed on one of the electronic units 14 and at least partially overlapped with one of the protruding units 16. The optical element 28 may, for example, serve as an anti-reflection layer to reduce the influence of ambient light on the image generated by the electronic device 3. According to this embodiment, the electronic device 3 may include a plurality of optical elements 28 disposed on the insulating layer IN8. The optical elements 28 may include, for example, a plurality of optical elements 28a, a plurality of optical elements 28b, and a plurality of optical elements 28c, wherein the optical elements 28a may respectively overlap the electronic units 14a, the optical elements 28b may respectively overlap the electronic units 14b, and the optical elements 28c may respectively overlap the electronic units 14c. The optical elements 28a, 28b, and 28c may include, for example, quantum dot materials, color filter materials, or other materials capable of altering the wavelength of light. Furthermore, depending on the used material, the optical elements 28a, 28b, and 28c may respectively have different colors or generate light of different colors. For example, when the electronic units 14a, 14b, and 14c are respectively used to generate red, green, and blue light, the optical elements 28a, 28b, and 28c may be red filters, green filters, and blue filters, respectively, but not limited thereto.

In this embodiment, one of the protruding units 16 may simultaneously overlap at least two of the optical elements 28 having different colors, such as at least two of the optical elements 28a, 28b, and 28c, but not limited thereto. In some embodiments, the optical elements 28 with different colors may have different areas. For example, the optical elements 28a, 28b, and 28c may have different areas. In some embodiments, at least two of the optical elements 28a, 28b, and 28c may have overlapping areas with the protruding unit 16, and the overlapping areas may be the same or different.

As shown in FIG. 7, according to this embodiment, adjacent optical elements 28 may be separated from each other in the top view. In this case, the electronic device 3 may further include a light-shielding layer 32 disposed between adjacent optical elements 28. For example, the light-shielding layer 32 may be disposed on the insulating layer IN8 and may have a plurality of openings OP3 respectively corresponding to the electronic units 14 in the top view. The optical elements 28 may be respectively disposed within the openings OP3. In other words, the light-shielding layer 32 may be disposed on the protruding units 16. According to this embodiment, the light-shielding layer 32 may overlap or cover the sensing electrode 26 in the top view to shield the sensing electrode 26. The light-shielding layer 32 may include, for example, metal, black resin, black pigment, black dye, or other suitable materials, but not limited thereto. In some embodiments, the electronic device 3 may not include the light-shielding layer 32. In this case, adjacent optical elements 28 may overlap each other, and their overlapping portion may overlap the corresponding protruding unit 16. For example, the optical element 28a may overlap the optical element 28c, and their overlapping portions may be disposed on the protruding unit 16. The optical element 28 and/or the light-shielding layer 32 in this embodiment may be applicable to any of the embodiments described above or below. In some embodiments, when the electronic device 3 includes the sensing electrode 26, the electronic device 3 may not include the optical element 28 and/or the light-shielding layer 32. Alternatively, when the electronic device 3 includes the optical element 28 and/or the light-shielding layer 32, the electronic device 3 may not include the sensing electrode 26.

According to this embodiment, at least one of the electronic units 14 (e.g., the electronic unit 14c) may have a bottom electrode E7 that is at least partially overlapped with the protruding unit 16, but not limited thereto. The structure in which the bottom electrode E7 overlaps the protruding unit 16 in this embodiment may be applicable to any of the embodiments described above or below. In some embodiments, the bottom electrode E7 shown in FIG. 7 may alternatively not overlap the protruding unit 16.

In the embodiment shown in FIG. 6, a top-view shape of the protruding unit 16 takes a circular shape as an example. The protruding unit 16 includes a point P5, a point P6, and a central axis CA, wherein the central axis CA passes through the points P5 and P6, and the points P5 and P6 are located on the edge (i.e., the circumference) of the protruding unit 16. The circular protruding unit 16 may be applicable to any of the embodiments described above or below. Other portions of the electronic device 3 in this embodiment may be the same as or similar to those of the electronic device 1 shown in FIG. 1 or FIG. 2, or the electronic device 2 shown in FIG. 3, and thus reference may be made to the above descriptions, which will not be repeated here.

Refer to FIG. 8, which schematically illustrates a top view of an electronic device operated in the first state according to a fourth embodiment of the present disclosure. One of main differences between the electronic device 4 provided in this embodiment and the electronic device 1 shown in FIG. 1 is that the top-view shape of the protruding unit 16 may be an irregular shape. For example, as shown in the enlarged view of the protruding unit 16 located at the upper right side of FIG. 8, one protruding unit 16e may have an asymmetric shape, for example, including a connecting part 16CP, a first part 16P1, and a second part 16P2, wherein the first part 16P1 and the second part 16P2 are connected to the connecting part 16CP, and an extending direction of the first part 16P1 is not parallel to an extending direction of the second part 16P2. Also, a length LE1 of the first part 16P1 is different from a length LE2 of the second part 16P2. According to this embodiment, the protruding unit 16e may further include a third part 16P3 connected to the connecting part 16CP, and an extending direction of the third part 16P3 may be parallel to the extending direction of the first part 16P1. In this case, the protruding unit 16e may be enclosed by the minimum rectangle R1, such that the minimum rectangle R1 is able to cover the entire protruding unit 16e. Since the sum of the length LE1 of the first part 16P1 and the length LE3 of the third part 16P3 may be greater than the length LE2 of the second part 16P2, the longitudinal direction LD1 of the protruding unit 16e may be parallel to the extending direction of the first part 16P1, and a short axis direction SD1 may be parallel to the extending direction of the second part 16P2, but not limited thereto. In this embodiment, the connecting part 16CP may refer to a junction between the first part 16P1 and the second part 16P2, and the connecting part 16CP is a part where the protruding unit 16e begins to exhibit a width different from that of the first part 16P1 (or the second part 16P2 or the third part 16P3), such as the part where the width starts to gradually increase.

In some embodiments, the first part 16P1, the second part 16P2, and the third part 16P3 of the protruding unit 16e may respectively have end points P7, P8, and P9, and a minimum distance D5 between the end point P7 and the edge E of the portion MP may be different from another minimum distance D6 between the end point P8 and the edge E of the portion MP. In some embodiments, another minimum distance D7 between the end point P9 and the edge E of the portion MP may be different from the minimum distances D5 and D6, but not limited thereto.

In some embodiments, edges of the protrusion unit 16e respectively corresponding to the end points P7, P8, and/or P9 in the top view may each optionally have a curved surface, but not limited thereto. In some embodiments, as shown in the enlarged view at the lower right side of FIG. 8, when one of the edges of the protrusion unit 16e has the curved surface, a curvature radius of the curved surface of the edge of the protrusion unit 16e may be greater than a curvature radius of a corner of one of the electronic units 14 (e.g., a corner 14CR of the electronic unit 14a), but not limited thereto. In some embodiments, when the protrusion unit 16e has a corner, a curvature radius of the corner of the protrusion unit 16e may be greater than a curvature radius of the corner 14CR of the electronic unit 14a, but not limited thereto.

In some embodiments, the electronic device 4 may further include a plurality of protruding units 16f disposed on the same portion MP. For example, the protruding units 16f may be formed by separating the second part 16P2 from the connecting part 16CP, while connecting the first part 16P1 to the third part 16P3 of the protruding unit 16e, but not limited thereto. In some embodiments, the electronic device 4 may further include a plurality of protruding units 16g disposed on the same portion MP, wherein the protruding units 16g may be formed by separating the first part 16P1, the second part 16P2, and the third part 16P3 of the protruding unit 16e from each other, but not limited thereto. The protruding unit 16e, the protruding units 16f, and/or the protruding units 16g shown in FIG. 8 may be applicable to any of the embodiments described above or below. Other portions of the electronic device 4 in this embodiment may be the same as or similar to those of the electronic devices in the above embodiments, and thus reference may be made to the above descriptions, which will not be repeated here.

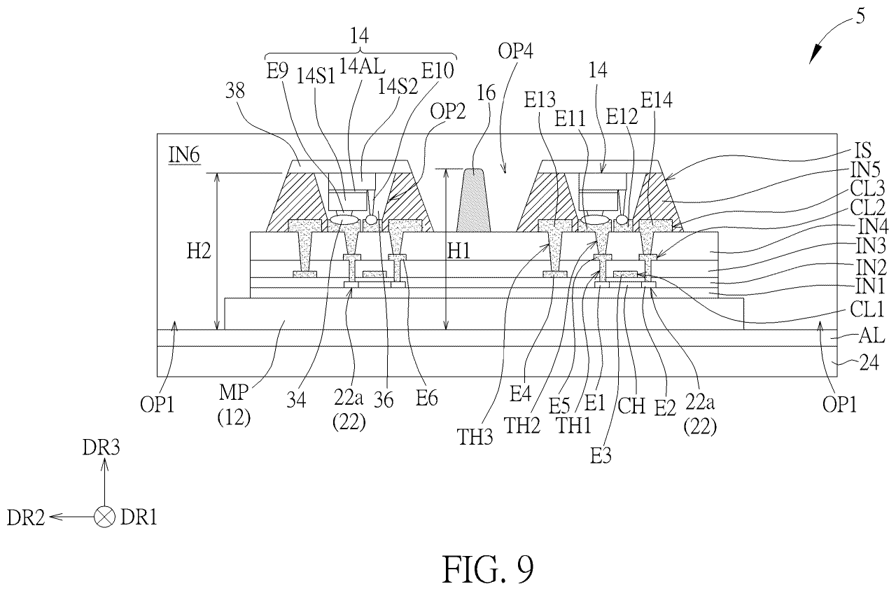

Refer to FIG. 9, which schematically illustrates a cross-sectional view of an electronic device according to a fifth embodiment of the present disclosure. One of main differences between the electronic device 5 provided in this embodiment and the electronic device shown in FIG. 4 is that the electronic unit 14 may be, for example, an inorganic light-emitting diode disposed in the opening OP2 of the insulating layer IN5. As shown in FIG. 9, the electronic unit 14 may include, for example, a semiconductor layer 14S1, a semiconductor layer 14S2, an active layer 14AL, a pad E9, and a pad E10, wherein the active layer 14AL is located between the semiconductor layer 14S1 and the semiconductor layer 14S2, the pad E9 is disposed on a surface of the semiconductor layer 14S1, and the pad E10 is disposed on a surface of the semiconductor layer 14S2, but not limited thereto. In this case, the conductive layer CL3 may include an electrode E11 and an electrode E12, and the pads E9 and E10 of the electronic unit 14 may be electrically connected and bonded to the electrodes E11 and E12 through bonding pads 34, respectively. According to this embodiment, the electrode E11 may further be electrically connected to the electrode E5 through the through hole TH2, such that the electronic unit 14 may be electrically connected to the transistor 22a through the electrodes E11 and E5, but not limited thereto.

In some embodiments, the conductive layer CL3 may further include an electrode E13 and an electrode E14, and the insulating layers IN3 and IN4 may further include a through hole TH3, such that the electrode E13 may be electrically connected to the electrode E4 through the through hole TH3. In addition, the electrode E14 may be electrically connected to the electrode E6 through another through hole TH2. The electrical connection structure between the electronic unit 14 and the transistor 22 in the present disclosure is not limited to the aforementioned and may be adjusted as needed.

As shown in FIG. 9, the electronic device 5 in this embodiment may optionally include a filling layer 36 disposed in the opening OP2 of the insulating layer IN5. In addition, the electronic device 5 may optionally include a cover layer 38 disposed on the electronic unit 14. According to this embodiment, as shown in FIG. 9, the insulating layer IN5 may further include an opening OP4 disposed between adjacent electronic units 14. The opening OP4 may penetrate through the insulating layer IN5 and expose the insulating layer IN4, and the protruding unit 16 may be disposed in the opening OP4 and located on the insulating layer IN4. The protruding unit 16 may protrude beyond the opening OP4. Namely, the thickness of the protruding unit 16 may be greater than the thickness of the insulating layer IN5, such that the protruding unit 16 may be higher than the electronic unit 14 in the normal direction (e.g., direction DR3), that is, the height H1 of the protruding unit 16 is greater than the height H2 of the electronic unit 14, but not limited thereto.

In FIG. 9, the electronic device 5 may further include an adhesive layer AL for attaching the stretchable pattern substrate 12 to the flexible substrate 24. The electronic unit 14 shown in FIG. 9 may be applicable to any of the embodiments described above or below. Other portions of the electronic device 5 in this embodiment may be the same as or similar to those of the electronic devices in the above embodiments, and thus reference may be made to the above descriptions, which will not be repeated here.

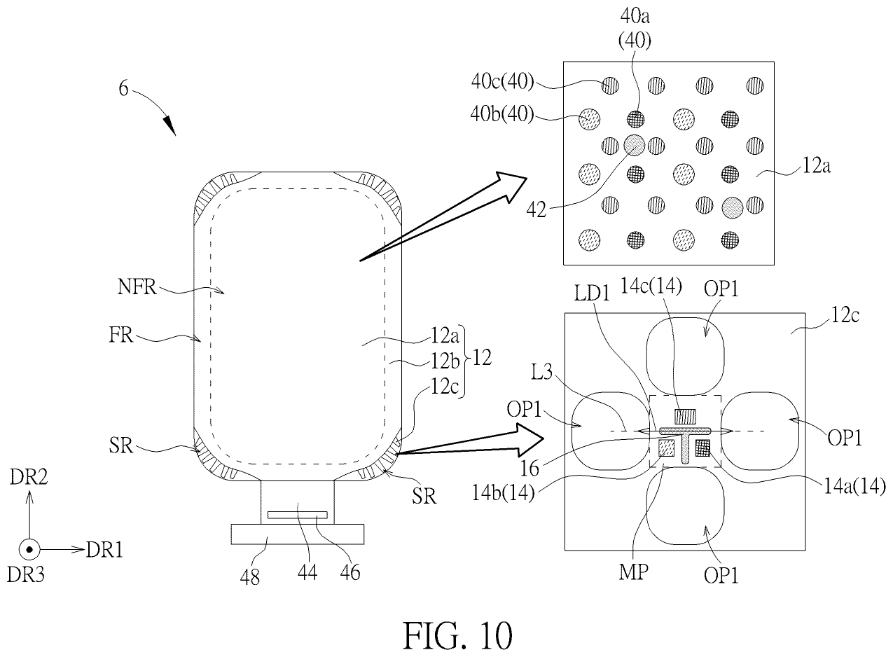

Refer to FIG. 10, which schematically illustrates a top view of an electronic device operated in the first state according to a sixth embodiment of the present disclosure. The electronic device 6 provided in this embodiment may include a non-flexible region NFR and at least one stretchable region SR, wherein the non-flexible region NFR may not have bending or flexing characteristic, while the stretchable region SR may have stretchable and bendable characteristics. According to this embodiment, the electronic device 6 may include four stretchable regions SR and may further include four flexible regions FR, wherein the flexible regions FR are connected to four sides of the non-flexible region NFR, and the stretchable regions SR are respectively connected between two adjacent flexible regions FR and disposed corresponding to the corners of the non-flexible region NFR. For example, the stretchable pattern substrate 12 may include a non-flexible portion 12a, a plurality of flexible portions 12b, and a plurality of stretchable portions 12c, wherein the non-flexible portion 12a may be disposed in the non-flexible region NFR, the flexible portions 12b may be respectively disposed in the flexible regions FR, and the stretchable portions 12c may be respectively disposed in the stretchable regions SR, but not limited thereto. According to this embodiment, the stretchable portion 12c may have, for example, a fringe shape, but not limited thereto.

As shown in the enlarged view of a portion of the non-flexible region NFR at the upper right side of FIG. 10, the non-flexible portion 12a does not include the openings OP1, and the electronic device 6 may include a plurality of electronic units 40 and a plurality of protruding units 42 disposed on the non-flexible portion 12a. The electronic units 40 may include, for example, a plurality of electronic units 40a, a plurality of electronic units 40b, and a plurality of electronic units 40c, wherein the electronic units 40a, 40b, and 40c may be respectively used to generate light of different colors, such as red, green, and blue light, but not limited thereto. In the embodiment shown in FIG. 10, the protruding units 42 may be disposed on a portion of the non-flexible portion 12a where no electronic units 40 are disposed on, for example, between adjacent electronic units 40. Since the electronic units 40 may be the same as or similar to the electronic units 14, reference may be made to the above descriptions, which will not be repeated here. The top-view shape of the protruding units 42 in this embodiment may be circular or any other suitable shape, but not limited thereto.

In the enlarged view of a portion of the stretchable region SR at the lower right side of FIG. 10, the stretchable portion 12c may include a plurality of openings OP1. In this embodiment, the main difference between the stretchable portion 12c and the stretchable pattern substrate 12 shown in FIG. 1 lies in the shape and arrangement of the openings OP1, while the reference of other portions of the stretchable portion 12c may made to the above descriptions, which will not be repeated here. Furthermore, the protruding unit 16 in this embodiment may be the same as the protruding unit 16e shown in FIG. 8, and thus reference may be made to the above descriptions, which will not be repeated here. In some embodiments, the protruding unit 16 may alternatively be replaced with any of the protruding units 16 described in the above embodiments. According to this embodiment, a connecting line L3 of centers of two openings OP1 respectively disposed on opposite sides of the stretchable portion 12c may coincide with the longitudinal direction LD1 of the protruding unit 16, thereby facilitating stretching.

In some embodiments, the top-view shape of the protruding unit 16 in the stretchable region SR may be different from that of the protruding unit 42 in the non-flexible region NFR, such that the shapes of the protruding unit 16 and the protruding unit 42 may be adjusted according to different requirements. In some embodiments, the height of the protruding unit 16 in the stretchable region SR (e.g., the height H1 shown in FIG. 4 or FIG. 9) may be different from the height of the protruding unit 42 in the non-flexible region NFR. For example, the height of the protruding unit 16 may be less than that of the protruding unit 42. In some embodiments, the top-view area of the protruding unit 16 in the stretchable region SR may be less than that of the protruding unit 42 in the non-flexible region NFR, thereby facilitating the placement of the protruding unit 16, but not limited thereto. In some embodiments, the height of the pixel defining layer in the stretchable region SR (e.g., the insulating layer IN5 shown in FIG. 4) may be less than the height of the pixel defining layer in the non-flexible region NFR (e.g., the insulating layer IN5 shown in FIG. 4), but not limited thereto.

As shown in FIG. 10, the electronic device 6 may further include a flexible circuit board 44, a bonding pad 46, and a control element 48, wherein the flexible circuit board 44 is connected to one of the flexible portions 12b, the bonding pad 46 may be disposed on the flexible circuit board 44, and the control element 48 may be bonded to the flexible circuit board 44, but the present disclosure is not limited thereto. The non-flexible region NFR and the flexible region FR shown in FIG. 10 may be applicable to any of the embodiments described above. Other portions of the electronic device 6 in this embodiment may be the same as or similar to those of the electronic devices in the above embodiments, and thus reference may be made to the above descriptions, which will not be repeated here.

In summary, in the electronic device of the present disclosure, since the distance between the protruding units disposed on different island portions may be increased after stretching, the electronic device may exhibit noticeable change in size after being stretched. Therefore, the change is able to be easily recognized by the human eye, such that the electronic device has the stretchable characteristic. Furthermore, by disposing at least a part of the protruding unit in the central region of the island portion of the stretchable pattern substrate, the protruding unit may achieve better support performance and provide improved support while occupying minimal area.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, which has a first state and a second state, the electronic device comprising:
a stretchable pattern substrate having a first portion, a second portion, and a connecting portion connected between the first portion and the second portion;
a first electronic unit and a first protruding unit disposed on the first portion; and
a second electronic unit and a second protruding unit disposed on the second portion,
wherein the first protruding unit and the second protruding unit are higher than the first electronic unit and the second electronic unit in a normal direction of the electronic device, and
wherein when the electronic device is extended along a stretched direction from the first state to the second state, a first distance D1 is present between the first protruding unit and the second protruding unit along the stretched direction in the first state, a second distance D2 is present between the first protruding unit and the second protruding unit along the stretched direction in the second state, and the first distance D1 and the second distance D2 satisfy a following relationship: 1<D2/D1<2.

2. The electronic device of claim 1, wherein when the electronic device is extended along the stretched direction from the first state to the second state, the first protruding unit and the second protruding unit are different in direction of rotation.

3. The electronic device of claim 1, wherein when the electronic device is extended along the stretched direction from the first state to the second state, the first protruding unit and the second protruding unit are the same in direction of rotation.

4. The electronic device of claim 1, wherein when the electronic device is extended along the stretched direction from the first state to the second state, a rotation angle of the first protruding unit relative to the first electronic unit is greater than zero.

5. The electronic device of claim 1, wherein when the electronic device is in the first state, the first protruding unit is arranged in a first longitudinal direction, the second protruding unit is arranged in a second longitudinal direction not parallel to the first longitudinal direction.

6. The electronic device of claim 5, wherein when the electronic device is extended along the stretched direction from the first state to the second state, a first acute angle between the first longitudinal direction and the stretched direction is different from a second acute angle between the second longitudinal direction and the stretched direction.

7. The electronic device of claim 1, further comprising a third electronic unit and a fourth electronic unit disposed on the first portion, wherein the first protruding unit is surrounded by the first electronic unit, the third electronic unit, and the fourth electronic unit.

8. The electronic device of claim 1, wherein a minimum distance D3 is present between an edge of the first portion and the first protruding unit along a direction, the first protruding unit has a maximum width W1, and the minimum distance D3 and the maximum width W1 satisfy another following relationship: 0<D3≤W1.

9. The electronic device of claim 1, wherein the first protruding unit has a first end point and a second end point, and a minimum distance between the first end point and an edge of the first portion is different from a minimum distance between the second end point and the edge of the first portion.

10. The electronic device of claim 9, wherein the first protruding unit is arranged in a longitudinal direction, the first protruding unit has a central axis, and the central axis is parallel to the longitudinal direction and passes through the first end point and the second end point.

11. The electronic device of claim 1, wherein the first protruding unit has a first point, a second point, and a central axis, and the central axis passes through the first point and the second point.

12. The electronic device of claim 1, wherein the first protruding unit has a connecting part, a first part, and a second part, the first part and the second part are connected to the connecting part, an extending direction of the first part is not parallel to an extending direction of the second part, and the first part and the second part are different in length.

13. The electronic device of claim 1, further comprising a sensing electrode disposed on the first portion, wherein the sensing electrode surrounds the first electronic unit and the first protruding unit.

14. The electronic device of claim 13, further comprising a third electronic unit disposed on the first portion, wherein the sensing electrode has an opening, and the first electronic unit, the third electronic unit, and the first protruding unit are disposed in the opening.

15. The electronic device of claim 1, further comprising a first optical element disposed on the first electronic unit and at least partially overlapped with the first protruding unit.

16. The electronic device of claim 15, further comprising a sensing electrode disposed on the first portion and surrounding the first electronic unit, the first optical element, and the first protruding unit.

17. The electronic device of claim 1, wherein the first electronic unit has a bottom electrode at least partially overlapped with the first protruding unit.

18. The electronic device of claim 1, further comprising an insulating layer disposed on the first portion, wherein the first protruding unit is disposed on the insulating layer, and in the normal direction, a thickness of the first protruding unit is greater than a thickness of the insulating layer.

19. The electronic device of claim 1, further comprising an insulating layer disposed on the first portion, wherein the first protruding unit is disposed on the insulating layer, and in a cross-sectional view, an acute angle between a side of the first protruding unit and a surface of the first portion is less than an acute angle between a side of the insulating layer and the surface of the first portion.
